(19) United States
(12) Patent Application Publication
(10) Pub. No.: US 2026/0141961 A1
(43) Pub. Date: May 21, 2026

(54) POWER EFFICIENT CHARGE RECYCLING

(71) Applicant: Micron Technology, Inc., Boise, ID (US)

(72) Inventors: Shawn Storm, Sunnyvale, CA (US); Qinge Li, Sunnyvale, CA (US); Yankang He, Mountain View, CA (US); Aleksey Prozapas, Kuna, ID (US); Nathan Dean Wood, Boise, ID (US); Jeremy Binfet, Boise, ID (US)

(73) Assignee: Micron Technology, Inc., Boise, ID (US)

(21) Appl. No.: 19/388,989

(22) Filed: Nov. 13, 2025

Related U.S. Application Data
(60) Provisional application No. 63/722,255, filed on Nov. 19, 2024.
(60) Provisional application No. 63/722,559, filed on Nov. 19, 2024.

(51) Int. Cl. G11C 16/30; G11C 5/06; G11C 16/04; G11C 16/08

(52) U.S. Cl. CPC G11C 16/30; G11C 5/063; G11C 16/0483; G11C 16/08

(57) ABSTRACT

A method performed by a memory device for power efficient charge recycling is provided. The method comprises, during the first operation, causing the target block to provide electrical energy to charge the storage block to a first voltage. The method further comprises discharging the word line coupled to the target block. The method further comprises, during the second operation, determining if the first voltage is greater than or equal to a storage block voltage threshold. The method further comprises, in accordance with a determination that the first voltage is greater than or equal to the storage block voltage threshold, causing the storage block to provide stored electrical energy to charge the target block to a second voltage.

### RELATED APPLICATIONS

This application claims priority to U.S. Provisional Application No. 63/722,255, filed on Nov. 19, 2024, entitled “POWER EFFICIENT CHARGE RECYCLING” and U.S. Provisional Application No. 63/722,559, filed on Nov. 19, 2024, entitled “POWER EFFICIENT CHARGE RECYCLING.” The contents of U.S. Provisional Application No. 63/722,255 and U.S. Provisional Application No. 63/722,559 are incorporated herein in their entirety for all purposes.

### TECHNICAL FIELD

This disclosure relates to one or more systems for memory, including techniques for power efficient charge recycling.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 is a timing diagram illustrating a memory access operation on a target memory block in accordance with examples as disclosed herein.

FIG. 5A is a timing diagram illustrating a first charge-sharing process between a target block and a storage block during the discharge stage of the target block, in accordance with examples as disclosed herein.

FIG. 5B illustrates simplified circuit diagrams showing the first charge-sharing process at different time intervals during the discharge stage of the target block, in accordance with examples as disclosed herein.

FIG. 6A is a timing diagram illustrating a second charge-sharing process between the target block and the storage block during a subsequent ramp-up stage of the target block, in accordance with examples as disclosed herein.

FIG. 6B illustrates simplified circuit diagrams showing the second charge-sharing process at different time intervals during the subsequent ramp-up stage of the target block, in accordance with examples as disclosed herein.

FIG. 7 is a timing diagram illustrating multiple memory access operations when the charge-sharing scheme is applied in accordance with examples as disclosed herein.

FIG. 8 illustrates a schematic diagram showing switches connecting a target block and a storage block in a memory array, in accordance with examples as disclosed herein.

FIG. 9 is a flowchart illustrating a method for performing charge-sharing between a target block and a storage block in a memory access operation that supports techniques for power efficient charge recycling, in accordance with examples as disclosed herein.

FIG. 10 is a flowchart illustrating another method for performing charge-sharing between a target block and a storage block in two memory access operations that supports techniques for power efficient charge recycling, in accordance with examples as disclosed herein.

### DETAILED DESCRIPTION

In a NAND device, substantial energy is required to ramp up word line voltages of a target memory block during a memory access operation. Since a memory block can be modeled as an equivalent capacitor, this energy is temporarily stored in the target memory block. However, at the end of the memory access operation, the word line voltages are discharged, and the stored energy dissipates as heat. This process not only increases device temperature, which can negatively impact system performance, but also results in energy waste.

The present disclosure addresses these issues by introducing new methods that captures and recycles the energy temporarily stored in a target memory block. Through a series of charge-sharing processes, the energy stored in the target memory block during the discharge stage of a previous memory access operation is transferred to a designated storage memory block, where it can be reused during the ramp-up stage of a subsequent operation. This charge-sharing scheme can achieve maximum efficiency across multiple memory access operations. As a result, the NAND device's overall energy management can be improved.

In one embodiment, during the discharge stage of a memory access operation, the memory controller connects the target memory block to the storage memory block by turning on a series of switches so that the two blocks can charge-share. After the charge-share, the two blocks are disconnected. As a result of this process, a portion of energy temporarily stored in the target memory block is transferred to the storage memory block. Then, in the ramp-up stage of a subsequent memory access operation, the memory controller reconnects the target memory block to the storage memory block so that the two blocks can charge-share again. At this time, a portion of the energy previously transferred to the storage memory block is now transferred back to the target memory block. As a result, a portion of the energy required for ramping up the word line voltage of the target memory block is being saved.

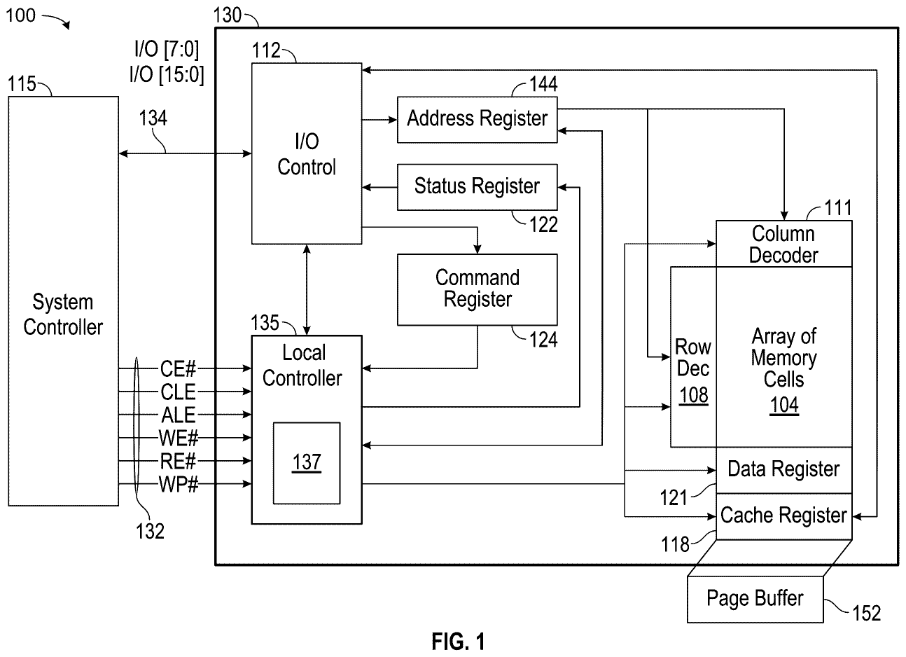

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

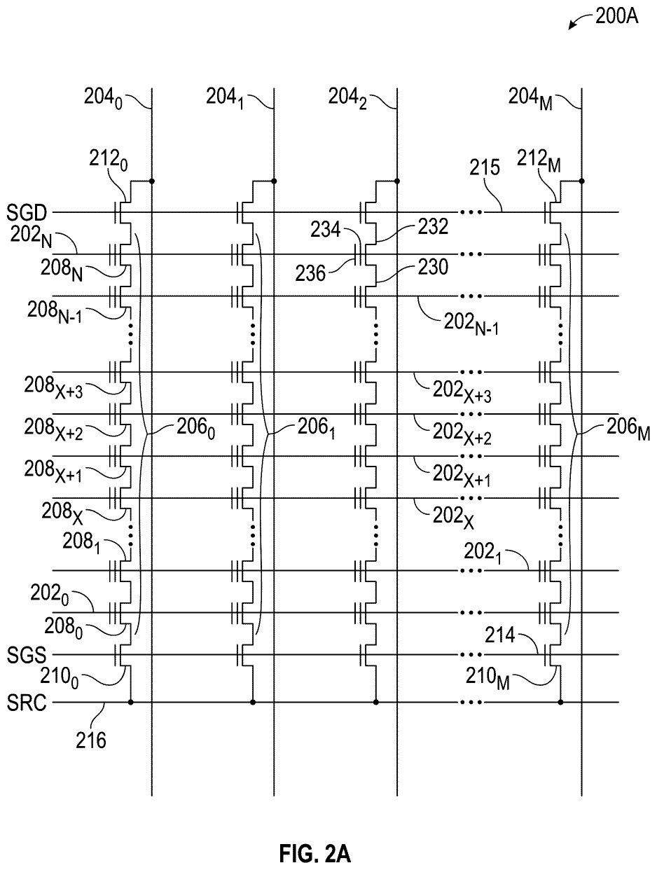

FIG. 2A-2B are example schematics of portions of an array of memory cells 200A, such as a NAND memory array. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

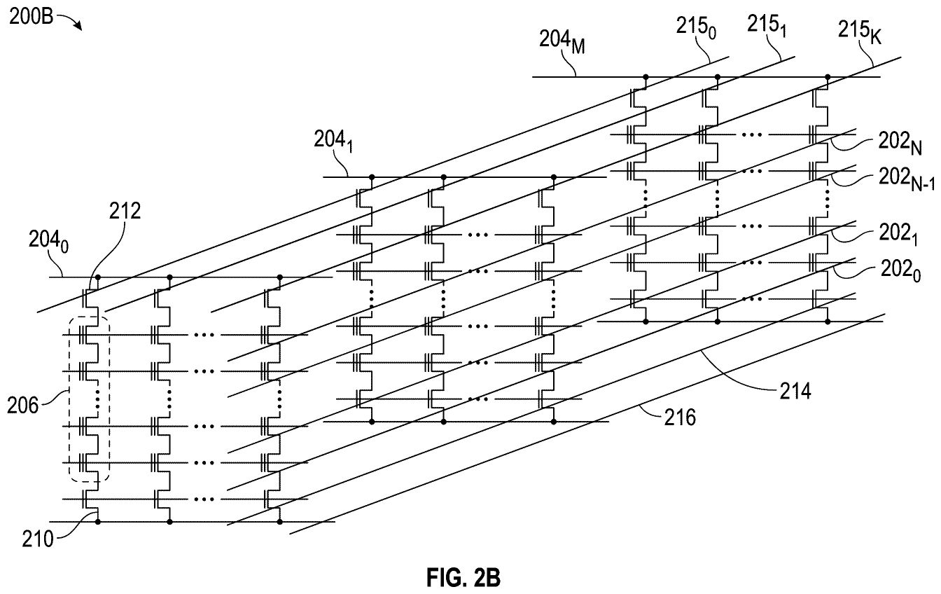

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-10, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-10 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-10. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

In this disclosure, the memory cell that is the target of a specific memory access operation is referred to as “selected memory cell” or “target memory cell”. The memory block where the target memory cell is located is referred to as “selected memory block”, “target memory block”, or “target block”. In the target memory block, the word line associated with the selected memory cell is referred to as the “target word line” or the “selected word line”. The other word lines in the target memory block are referred to as the “unselected word lines”.

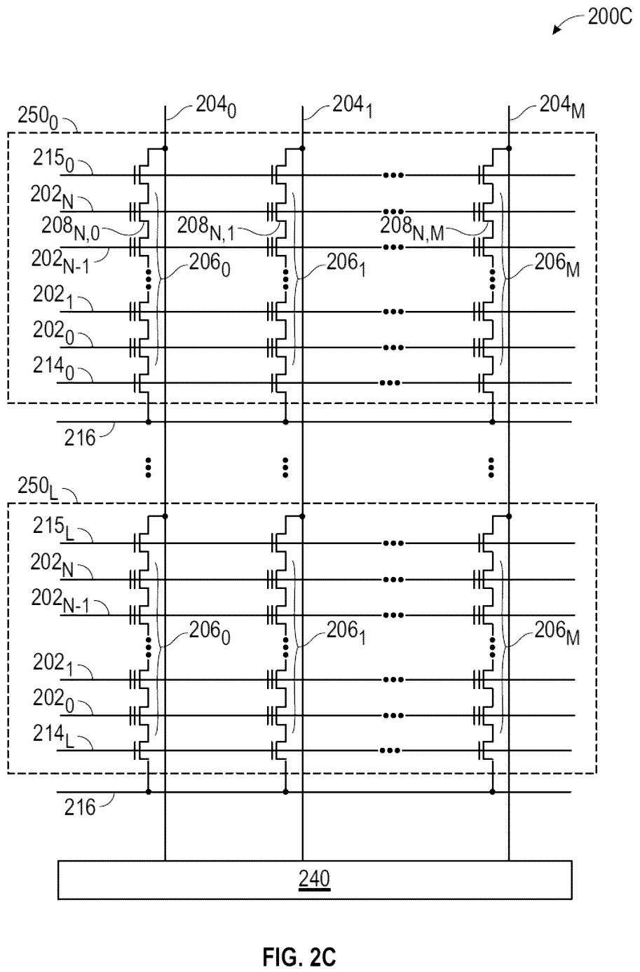

FIG. 4 is a timing diagram illustrating a memory access operation on a target memory block in accordance with examples as disclosed herein. The horizontal axis represents the lapse of time during a memory access operation, such as a memory read operation. Time intervals t₀-t₁, t₁-t₂, and t₂-t₃ correspond to three stages of a memory access operation, namely, the ramp-up stage, the page-read operation stage, and the discharge stage. The vertical axis represents voltages of the selected and/or the unselected word lines. Trace 401 depicts word line voltages at each stage. With reference to FIG. 2C, in one example, the target memory block is 250₀. The selected memory cell is memory cell 208_{N,0}, The selected world line is 202_{N}, and the unselected word lines are 202₀ to 202_{N-1}. In this example, the memory cells are of the TLC type (tri-level cells).

During the ramp-up stage (t₀-t₁), a memory controller (e.g., local controller 135 as shown in FIG. 1) controls voltage generation devices (such as word line pumps) to increase bias voltage on both the selected and unselected word lines of target block 250₀. The word line voltage ramps up from an initial voltage V₀ (at point 410) to a higher voltage V₄ (at point 414). In one embodiment, V₀ may be 0V, while V₄ could correspond to Vₚₐₛₛ, which is a voltage level high enough to turn on all the memory cells on string 206₀. In one example, voltages of both the selected and unselected word lines reach the same level at time t₁. In other examples, voltages of the selected and unselected word lines may reach different levels at time t₁. For example, while the voltage of the unselected word lines may reach Vₚₐₛₛ, the voltage of the selected word line may reach a different level (not shown in the figure).

During the page-read operation stage (t₁-t₂), the memory controller maintains voltage of the unselected word lines at Vₚₐₛₛ (not shown in the figure) and performs multiple page-read operations on the selected word line 202_{N} to ascertain the actual threshold level of the selected memory cell 208_{N,0}. Since the selected memory cell in this example is TLC, multiple page reads are performed to read the lower, upper or extra pages of the memory cell. The final page-read occurs at point 415 at time t₂. It should be noted that the page-read sequence illustrated in the figure is merely an example. The memory controller may employ different read sequences. In the example shown, a forward read sequence is applied where the voltage is applied from low to high during the reading of each page. In other examples, a reverse read sequence may be applied where the reading order of each page is reversed.

During the discharge stage (t₂-t₃), the voltage of the selected word line is equilibrated with the voltage of the unselected word line to level V₃ (point 416). Then, all word line voltages are discharged to level V₀ (point 420 at time t₃).

A memory block can be modeled as an equivalent capacitor. Referring back to FIG. 2C, in the target memory block 250₀, there are N+1 word lines, and each word line is coupled to M+1 memory cells. Assuming each memory cell has a gate-to-channel capacitance C_{gc}, and that there are K active pillars in the target block during a particular memory read operation, the equivalent capacitance C_{target} of the target block during the read operation can be expressed as C_{target}=K×(N+1)×C_{gc}.

At the end of the ramp-up stage, assuming the equivalent capacitance of the target block is fully charged, the energy stored in the target block can be expressed by the following equation (1):

$$E = \frac{1}{2} {C}_{target} {V}^{2} \qquad ( 1 )$$

where V=V₄. In the subsequent discharge stage, this stored energy is dissipated as heat. This process not only leads to increase in device temperature, which can negatively impact system performance, but also results in energy waste. The present disclosure introduces new solutions for capturing and reusing this energy (also referred to as the “reusable target block energy” or “reusable energy” in this disclosure), thereby reducing device temperature and conserving power.

The solution involves utilizing additional storage capacitors in the memory device to capture and store the reusable energy from the target block during its discharge stage. Then in the subsequent ramp-up stage, this stored reusable energy may be reused to drive the bias voltage on the word lines, thereby saving energy. Several methods may be employed to implement this solution. One approach is to create additional storage capacitors on the NAND die for storage and recharge purposes. Another approach is to create additional routings to utilize off-die capacitors for the purposes. A third approach is to designate certain memory blocks within the memory array as “storage blocks” that function as additional storage capacitors. The third approach is described in more detail below.

During the manufacturing process of a NAND chip, certain memory blocks may have been designated as unusable for memory access operations based on their behavior or intended purpose. For example, some memory blocks may be marked as unusable when they may serve as testing, redundant, or reserved blocks. However, while these memory blocks cannot be used for standard memory access operations, they are electrically equivalent to capacitors and can function as storage blocks for the purposes described in this disclosure. During the manufacturing process of a NAND chip, at least one memory block in a memory plane can be predetermined and marked as a designated storage block. If multiple memory blocks in a memory plane are marked as unusable after the manufacturing process, a memory controller may, at runtime, select one of these blocks as the designated storage block.

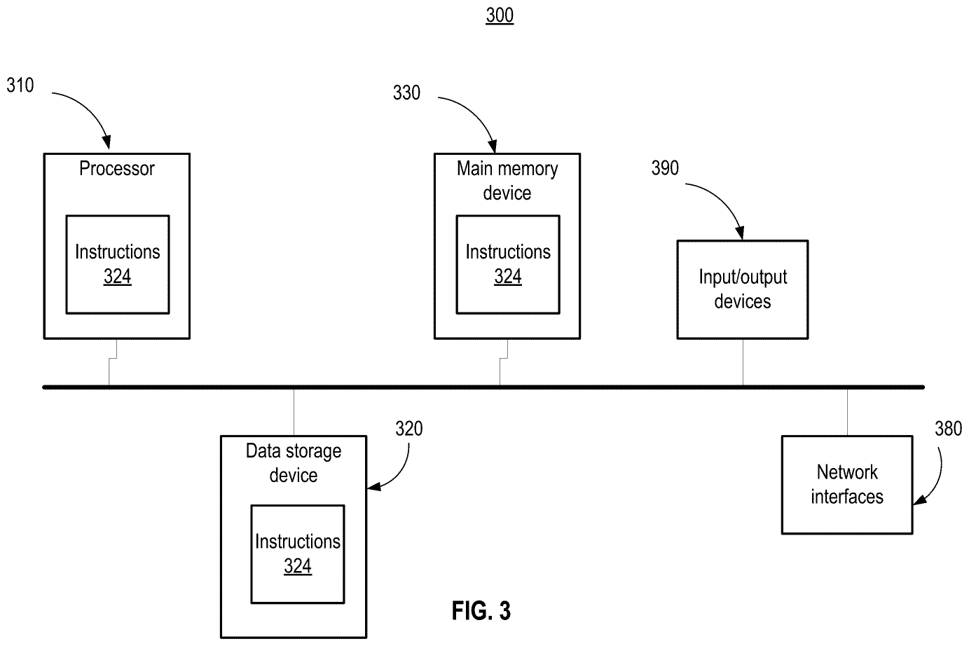

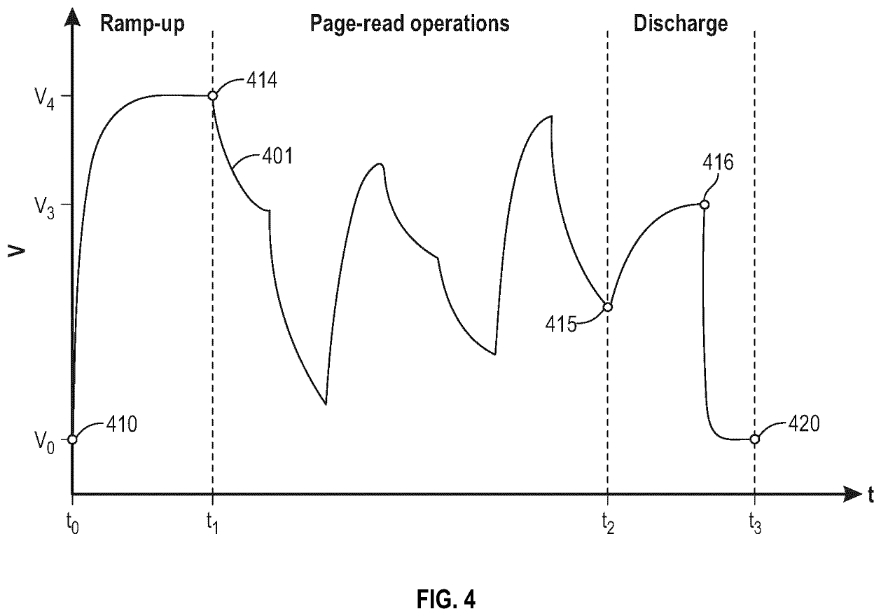

The reusable energy from the target block can be captured and stored by the designated storage block through charge sharing between two equivalent capacitors. FIG. 5A is a timing diagram illustrating a first charge-sharing process between a target block and a storage block during the discharge stage of the target block, in accordance with examples as disclosed herein. The horizontal axis represents the lapse of time during the discharge stage of the target block at time intervals t₂ to t₃. The vertical axis represents word line voltages of the target block and the storage block. Trace 501 depicts word line voltages of the target block, while trace 502 depicts word line voltages of the storage block.

FIG. 5B illustrates simplified circuit diagrams showing the first charge-sharing process at different time intervals during the discharge stage of the target block, in accordance with examples as disclosed herein. Capacitor 531 represents the capacitor equivalent to the target block, and capacitor 532 represents the capacitor equivalent to the storage block. The two capacitors are connected via switch 540. Referring to FIGS. 5A and 5B together, point 515 at time t₂ corresponds to the voltage level of the selected word line at the final page-read instance in the preceding page-read operation stage. From time t₂ to time t₂ₐ, the word line voltages of the target block are equilibrated to level V₃ (point 516). At the same time, word line voltage of the storage block remains at V₀. The top diagram of FIG. 5B shows the state of the target block and the storage block at time t₂ₐ. At this point, switch 540 is turned off. Word line voltage of the target block (sometimes referred to as V_{target} in this disclosure) is at V₃, and word line voltage of the storage block (sometimes referred to as V_{storage} in this disclosure) is at V₀.

As illustrated in the middle diagram of FIG. 5B, from time t₂ₐ to time t_{2b}, switch 540 is turned on to enable the first charge-sharing between the two capacitors 531 and 532. When two capacitors with different initial voltages are connected in parallel for charge sharing, charge flows from the higher voltage capacitor to the lower voltage capacitor. Given sufficient time, the two capacitors will reach a common final voltage once the charge has been fully shared. If the target block has an equivalent capacitance Cₜ and an initial voltage Vₜ, and the storage block has an equivalent capacitance Cₛ and an initial voltage Vₛ, the common final voltage after charge sharing can be expressed by the following equation (2):

$${V}_{f i n a l} = \frac{{C}_{t} {V}_{t} + {C}_{s} {V}_{s}}{{C}_{t} + {C}_{s}} \qquad ( 2 )$$

In the example illustrated in FIG. 5B, assuming the equivalent capacitances of the target block and the storage block are approximately the same (Cₜ=Cₛ), and the initial voltages of the target block and the storage block at time t₂ₐ are V₃ and V₀, respectively, then at time t_{2b} the common final voltage after the first charge-sharing V₂ can be expressed by the following equation (3):

$${V}_{2} = \frac{1}{2} ( {V}_{3} + {V}_{0} ) \qquad ( 3 )$$

If we further assume that V₀ is 0V, then

$${V}_{2} = \frac{1}{2} {V}_{3} ,$$

which means that the common final voltage of both blocks after the first charge-sharing is half the initial voltage of the target block before the first charge-sharing. As a result of this charge-sharing process, V_{target} decreases from V₃ at point 516 to V₂ at point 518, while V_{storage} increases from V₀ at point 517 to V₂ at point 518.

As illustrated in the bottom diagram of FIG. 5B, at time t_{2b}, switch 540 is turned off to stop the first charge-sharing process between the target block and the storage block. From time t_{2b} to time t₃, V_{target} continues to discharge, reaching V₀ at time t₃ (point 520), while V_{storage} remains at V₂ until time t₃ (point 521). Thus, by the end of the discharge stage of the target block, the storage block has been charged to half of the equilibrated voltage

$$( {V}_{2} = \frac{1}{2} {V}_{3} ) ,$$

assuming Cₜ=Cₛ and V₀=0V. Based on equation (1), the energy stored in the storage block can be expressed by the following equation (4):

$${E}_{stored} = \frac{1}{4} {E}_{e q u i l i brate} \qquad ( 4 )$$

where E_{equilibrate} represents the energy level of the target block at the equilibrated voltage V₃ at time t₂ₐ. This stored energy may be used during the ramp-up stage of a subsequent memory access operation to drive the bias voltage on the word lines of the target block.

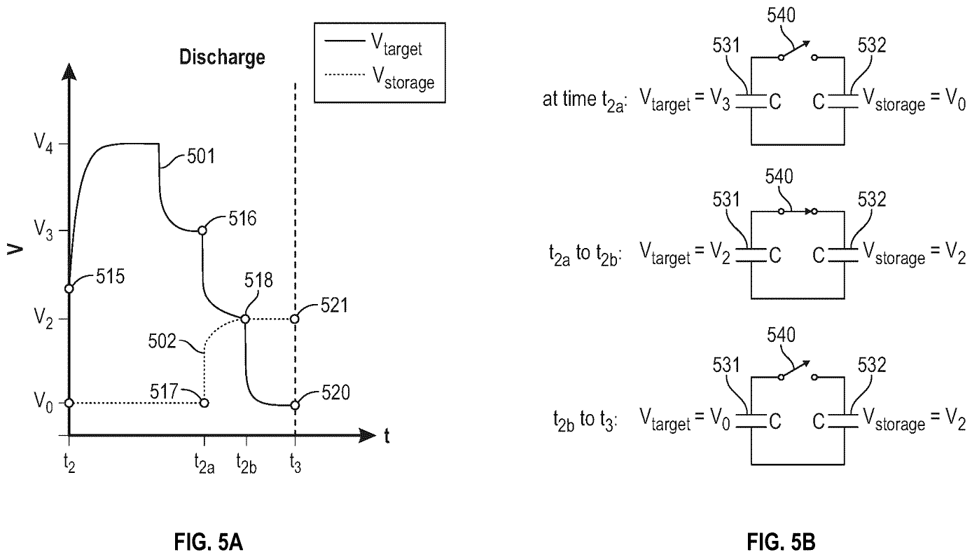

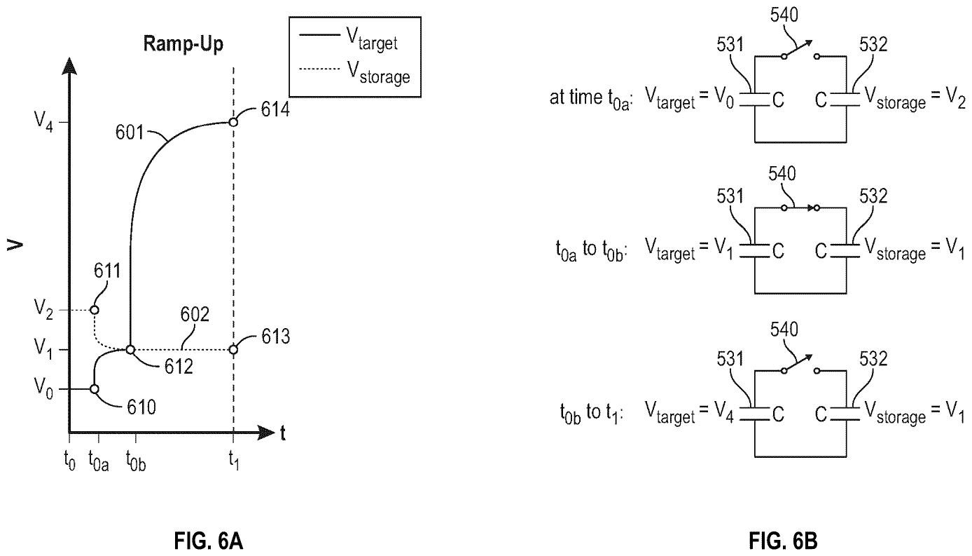

FIG. 6A is a timing diagram illustrating a second charge-sharing process between the target block and the storage block during a subsequent ramp-up stage of the target block, in accordance with examples as disclosed herein. The horizontal axis represents the lapse of time during a subsequent ramp-up stage of the target block at time intervals t₀ to t₁. The vertical axis represents word line voltages of the target block and the storage block. Trace 601 depicts word line voltages of the target block, while trace 602 depicts word line voltages of the storage block.

FIG. 6B illustrates simplified circuit diagrams showing the second charge-sharing process at different time intervals during the subsequent ramp-up stage of the target block, in accordance with examples as disclosed herein. Capacitor 531 represents the capacitor equivalent to the target block, and capacitor 532 represents the capacitor equivalent to the storage block. The two capacitors are connected via switch 540. Referring to FIGS. 6A and 6B together, the top diagram of FIG. 6B shows that from time t₀ to time t₀ₐ, switch 540 is turned off. V_{storage} remains at V₂ from the first charge-sharing process (point 611 at time t₀ₐ), and V_{target} remains at V₀ (point 610 at time t₀ₐ).

As illustrated in the middle diagram of FIG. 6B, from time t₀ₐ to time t_{0b}, switch 540 is turned on to enable a second charge-sharing process between the two capacitors 531 and 532. Based on equation (2) and again assuming Cₜ=Cₛ, at time t_{0b} (point 612) the common final voltage V₁ of both the target block and the storage block after the second charge-sharing can be expressed by the following equation (5):

$${V}_{1} = \frac{1}{2} ( {V}_{2} + {V}_{0} ) \qquad ( 5 )$$

If we further assume that V₀ is 0V, then

$${V}_{1} = \frac{1}{2} {V}_{2} = \frac{1}{4} {V}_{3} ,$$

which means that the common final voltage of both blocks after the second charge-sharing is ¼ of the initial voltage of the target block before the first charge-sharing. As a result of the second charge-sharing process, V_{target} increases from V₀ at point 610 to V₁ at point 612, while V_{storage} decreases from V₂ at point 611 to V₁ at point 612.

As illustrated in the bottom diagram of FIG. 6B, at time t_{0b}, switch 540 is turned off to stop the second charge-sharing process between the target block and the storage block. From time t_{0b} to time t₁, V_{target} continues to ramp-up to drive the bias voltage on the word lines of the target block, reaching V₄ at time t₁ (point 614), while V_{storage} remains at V₁ until time t₁ (point 613). Thus, compared to the ramp-up stage shown in FIG. 4, where the word line pumps must drive the word line voltage of the target block from V₀ to V₄, here the word line pumps only need to drive the word line voltage from V₁ to V₄. The energy required to raise the word line voltage from V₀ to V₁ is supplied by the energy previously stored in the storage block (E_{stored}). According to equation (4), the energy saved during the first and the second charge-sharing processes can be expressed as the following equation (6):

$${E}_{saved} = \frac{1}{4} {E}_{stored} = \frac{1}{16} {E}_{e q u i l i brate} \qquad ( 6 )$$

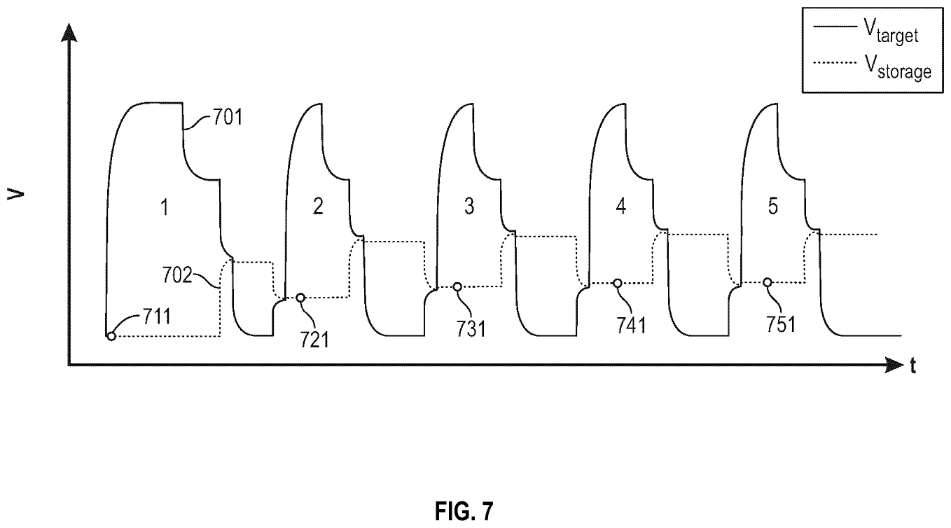

FIG. 7 is a timing diagram illustrating multiple memory access operations when the charge-sharing scheme is applied in accordance with examples as disclosed herein. The horizontal axis represents the lapse of time across multiple memory access operations on a target block. The vertical axis represents word line voltages of the target block and the storage block. Trace 701 depicts word line voltages of the target block, while trace 702 depicts word line voltages of the storage block. The diagram shows five consecutive memory access operations, with each operation labeled by its order number. For simplicity, the page-read operation stage of each memory access operation is omitted.

In the first memory access operation, V_{storage} begins at level 711 (e.g., 0V). After the first round of charge-sharing, which includes the first and the second charge-sharing processes, V_{storage} reaches level 721 during the second memory access operation. This level becomes the starting point for the next round of charge-sharing process. Accordingly, V₀ in equation (3) is higher in each subsequent round than in the previous one. V_{storage} continues to rise (reaching levels 731 and 741) during the subsequent memory access operations until it stabilizes at level 751 in the fifth operation. At this point, the charge-share scheme achieves its maximum efficiency.

It should be noted that five memory access operations are shown as an example. In practice, it may take any number of operations for V_{storage} to stabilize. Additionally, FIG. 7 represents memory access operations performed on a specific target block. Between any two consecutive memory access operations in FIG. 7, the memory controller may perform operations on other target memory blocks, which are not shown here.

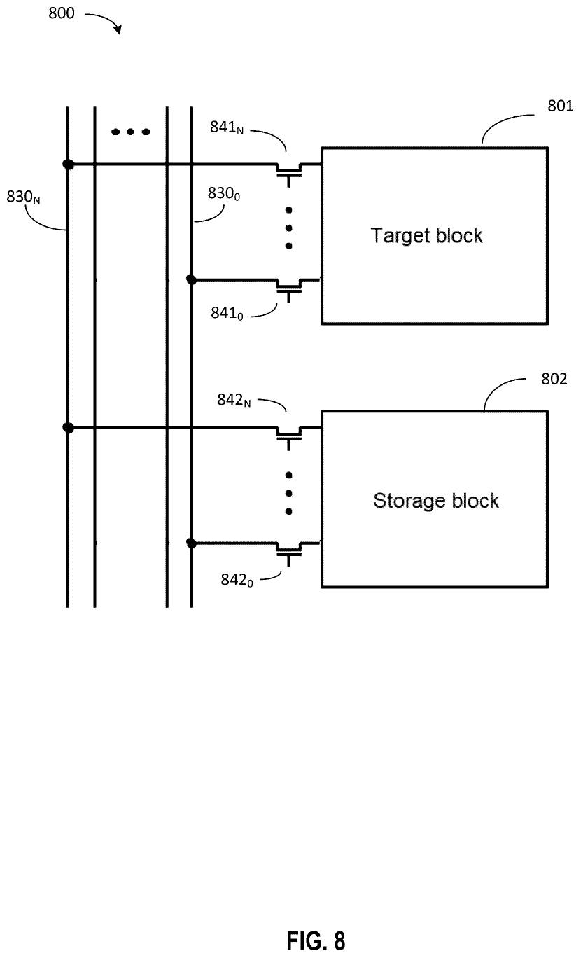

FIG. 8 illustrates a schematic diagram showing switches connecting a target block and a storage block in a memory array, in accordance with examples as disclosed herein. Memory array 800 includes two memory blocks, target block 801 and storage block 802. Each block has N+1 word lines, with each word line connected to a switch (shown as target block switches 841₀ to 841_{N} and storage block switches 842₀ to 842_{N}). The two memory blocks are connected to a series of connection lines 830₀ to 830_{N}, which link each memory block to voltage generation devices and ground.

During the ramp-up and discharge stages of target block 801, the target block switches are turned on (while the storage block switches remain off), allowing word line voltage of target block 801 to be ramped up by the voltage generation devices or discharged. In a charge-sharing process between target block 801 and storage block 802, both the target block switches and the storage block switches are turned on. These switches are part of the circuitry that connects or disconnects the storage block from the target block and are controlled by the memory controller.

In one embodiment, switch 540, shown in FIGS. 6A and 6B, represents all target block switches 841₀ to 841_{N} and storage block switches 842₀ to 842_{N}. When switch 540 is turned on, it indicates that both the target block switches and storage block switches are turned on at the same time. When switch 540 is turned off, it means that one or both sets of the switches are turned off.

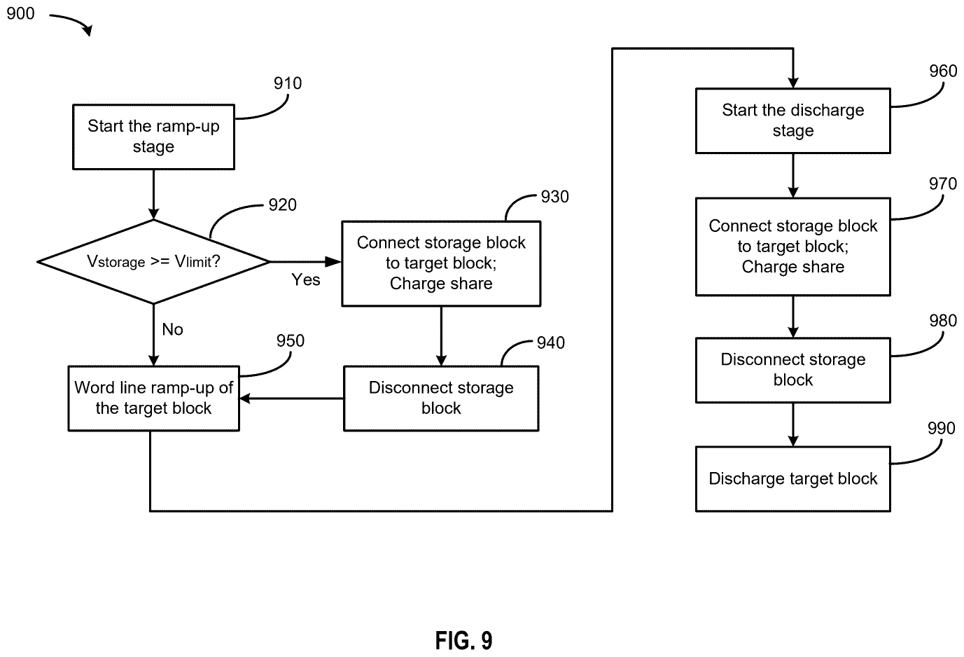

FIG. 9 is a flowchart illustrating method 900 for performing charge-sharing between a target block and a storage block in a memory access operation that supports techniques for power efficient charge recycling, in accordance with examples as disclosed herein. Method 900 may be performed by a memory device, or memory controllers in a memory device, such as host system controller, a system controller 115, and/or a local controller 135. In some embodiments, method 900 can be implemented in the form of firmware that is stored in computer readable medium and executed by local controller 135 to cause the memory device 130 to perform the operations described herein.

At block 910, the memory controller starts the ramp-up stage of a memory access operation on a target block. Referring back to FIG. 6A, this block corresponds to the start of the ramp-up stage at time t₀. At this point, the word line voltage of the storage block V_{storage} may have already been charged to V₂ through the charge-sharing scheme of a previous memory access operation.

At block 920, the memory controller determines if V_{storage} is greater than or equal to Vₗᵢₘᵢₜ, which is a storage block voltage threshold. The level of Vₗᵢₘᵢₜ is defined to ensure that there is enough stored energy in the storage block to charge-share with the target block and to ramp-up the word lines in the target block.

If it is determined that V_{storage} is less than Vₗᵢₘᵢₜ, the charge-sharing scheme will not be performed. At block 950, the memory controller controls word line pumps to ramp-up bias voltage on the target block word lines as illustrated in FIG. 4.

If it is determined that V_{storage} is greater than or equal to Vₗᵢₘᵢₜ, at block 930, the memory controller turns on switch 540 to connect the storage block and the target block to conduct the second charge-sharing process as illustrated in FIGS. 6A and 6B. At block 940, the memory controller turns off switch 540 at the end of the second charge-sharing process to disconnect the storage block from the target block. At this point, word line voltage of the target block V_{target} has been charged to V₁. After that, at block 950, the memory controller continues to ramp-up bias voltage on the target block word lines from V₁ to V₄, as illustrated in FIG. 6A.

Blocks 910 to 950 constitute the ramp-up stage of a memory access operation on the target block. At block 960, the memory controller starts the discharge stage of the same memory access operation on the target block (the page-read operation stage is omitted). Referring back to FIG. 5A, this block corresponds to discharge stage at time t₂ₐ. At this point, V_{storage} is at V₀ while V_{target} is at equilibrated level V₃.

At block 970, the memory controller turns on switch 540 to connect the storage block and the target block to conduct the first charge-sharing process as illustrated in FIGS. 5A and 5B. At block 980, the memory controller turns off switch 540 at the end of the first charge-sharing process to disconnect the storage block from the target block. At this point, V_{storage} has been charged from V₀ to V₂, and V_{target} has been decreased from V₃ to V₂. After that, at block 990, the memory controller continues to discharge the target block from V₂ to V₀, as illustrated in FIG. 5A.

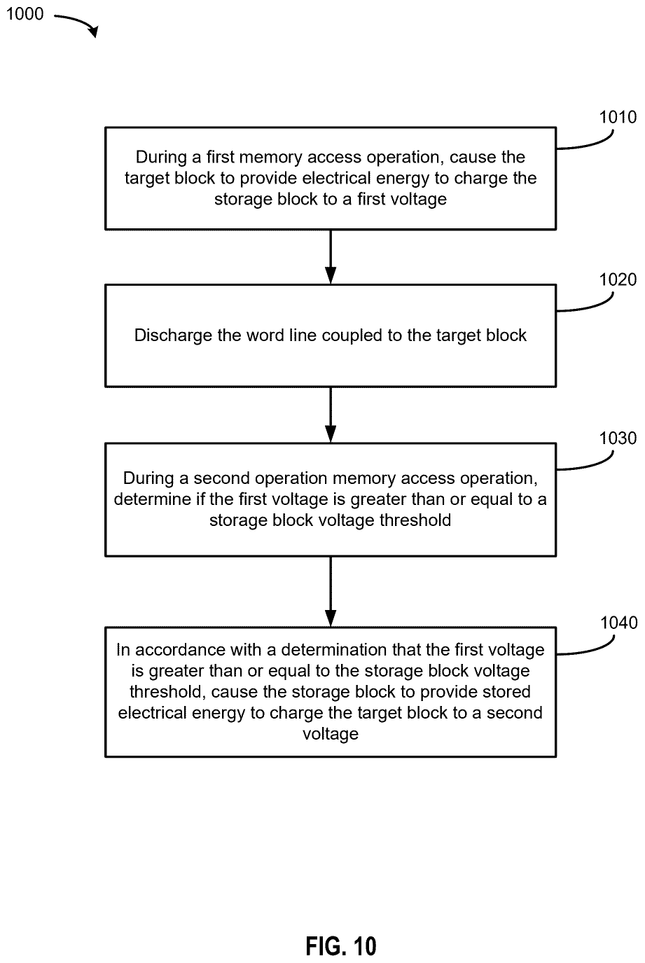

FIG. 10 is a flowchart illustrating method 1000 for performing charge-sharing between a target block and a storage block in two memory access operations that supports techniques for power efficient charge recycling, in accordance with examples as disclosed herein. Method 1000 may be performed by a memory device, or memory controllers in a memory device, such as host system controller, a system controller 115, and/or a local controller 135. In some embodiments, method 1000 can be implemented in the form of firmware that is stored in computer readable medium and executed by local controller 135 to cause the memory device 130 to perform the operations described herein.

At block 1010, the memory controller, during a first memory access operation, causes the target block to provide electrical energy to charge the storage block to a first voltage. Referring back to FIG. 5A, in one embodiment, during the discharge stage of the first memory access operation, the memory controller turns on switch 540 to connect the storage block and the target block to conduct the first charge-sharing process. At the end of the first charge-sharing process, the storage block has been charged from V₀ to the first voltage V₂.

At block 1020, the memory controller discharges the word line coupled to the target block. In one embodiment, the memory controller continues to discharge the target block to V₀ as illustrated in FIG. 5A.

At block 1030, the memory controller, during a second memory access operation, determines if the first voltage is greater than or equal to a storage block voltage threshold. Referring back to FIG. 9, in one embodiment, the memory controller determines if the first voltage is greater than or equal to the storage block voltage threshold Vₗᵢₘᵢₜ, which is defined to ensure that there is enough stored energy in the storage block to charge-share with the target block and to ramp-up the word lines in the target block.

At block 1040, the memory controller, in accordance with a determination that the first voltage is greater than or equal to the storage block voltage threshold, causes the storage block to provide stored electrical energy to charge the target block to a second voltage. If it is determined that the first voltage is greater than or equal to Vₗᵢₘᵢₜ, in one embodiment, the memory controller turns on switch 540 to connect the storage block and the target block to conduct the second charge-sharing process as illustrated in FIG. 6A. At the end of the second charge-sharing process, the target block has been charged by the storage block from V₀ to the second voltage V₁, thereby saving the word line pumps the electrical energy needed for driving the word line voltage of the target block from V₀ to V₁.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions of code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells comprising a target block and a storage block;
a plurality of word lines coupled to the array of memory cells, and
a memory controller configured to perform a plurality of access operations comprising a first operation and a second operation, wherein the memory controller is configured to:
during the first operation,
cause the target block to provide electrical energy to charge the storage block to a first voltage,
discharge the word line coupled to the target block; and
during the second operation,
determine if the first voltage is greater than or equal to a storage block voltage threshold, and
in accordance with a determination that the first voltage is greater than or equal to the storage block voltage threshold, cause the storage block to provide stored electrical energy to charge the target block to a second voltage.

2. The memory device of claim 1, wherein the second operation is subsequent to the first operation.

3. The memory device of claim 1, wherein causing the target block to provide electrical energy to charge the storage block to the first voltage comprises:
connecting the storage block to the target block such that a first charge-share is conducted to charge the storage block to the first voltage; and
disconnecting the storage block from the target block.

4. The memory device of claim 1, wherein causing the storage block to provide stored electrical energy to charge the target block to the second voltage comprises:
connecting the storage block to the target block such that a second charge-share is conducted to charge the target block to the second voltage; and
disconnecting the storage block from the target block.

5. The memory device of claim 1, wherein the memory controller is further configured to:
during the second operation,
increase bias voltages applied to the word lines coupled to the target block to a target bias voltage.

6. The memory device of claim 1, wherein the memory controller is further configured to:
during a word line discharge phase of the second operation, repeat steps performed during the first operation.

7. The memory device of claim 6, wherein the memory controller is further configured to:
during a word line ramp-up phase of an access operation subsequent to the second operation, repeat steps performed during the second operation.

8. The memory device of claim 1, wherein a capacitance of the storage block is approximately equal to a capacitance of the target block.

9. The memory device of claim 1, wherein the storage block is predetermined.

10. The memory device of claim 1, wherein the storage block is determined at runtime.

11. The memory device of claim 1, wherein the storage block is selected from a plurality of predefined storage blocks.

12. The memory device of claim 1, wherein the storage block voltage threshold is predetermined.

13. The memory device of claim 1, wherein the storage block voltage threshold is determined at runtime.

14. The memory device of claim 1, further comprising:
a circuitry configured to connect or disconnect the storage block to or from the target block.

15. A method performed by a memory device, the memory device comprising an array of memory cells comprising a target block and a storage block, a plurality of word lines coupled to the array of memory cells, and a memory controller configured to perform a plurality of access operations comprising a first operation and a second operation, the method comprising:
during the first operation,
causing the target block to provide electrical energy to charge the storage block to a first voltage, and
discharging the word line coupled to the target block; and
during the second operation,
determining if the first voltage is greater than or equal to a storage block voltage threshold, and
in accordance with a determination that the first voltage is greater than or equal to the storage block voltage threshold, causing the storage block to provide stored electrical energy to charge the target block to a second voltage.

16. The method of claim 15, wherein the second operation is subsequent to the first operation.

17. The method of claim 15, wherein causing the target block to provide electrical energy to charge the storage block to the first voltage comprises:
connecting the storage block to the target block such that a first charge-share is conducted to charge the storage block to the first voltage; and
disconnecting the storage block from the target block.

18. The method of claim 15, wherein causing the storage block to provide stored electrical energy to charge the target block to the second voltage comprises:
connecting the storage block to the target block such that a second charge-share is conducted to charge the target block to the second voltage; and
disconnecting the storage block from the target block.

19. The method of claim 15, further comprising:
during the second operation,
increase bias voltages applied to the word lines coupled to the storage block to a target bias voltage.

20. The method of claim 15, further comprising:
during a word line discharge phase of the second operation, repeat steps performed during the first operation.

21. The method of claim 20, further comprising:
during a word line ramp-up phase of an access operation subsequent to the second operation, repeat steps performed during the second operation.

22. The method of claim 15, wherein the storage block is predetermined.

23. The method of claim 15, wherein the storage block is determined at runtime.

24. A memory device comprising:
an input/output (I/O) circuit;
an array of memory cells comprising a target block and a storage block;
a plurality of word lines coupled to the array of memory cells, and
a memory controller configured to perform a plurality of access operations comprising a first operation and a second operation, wherein the memory controller is configured to:
during the first operation,
cause the target block to provide electrical energy to charge the storage block to a first voltage, and
discharge the word line coupled to the target block; and
during the second operation,
determine if the first voltage is greater than or equal to a storage block voltage threshold, and
in accordance with a determination that the first voltage is greater than or equal to the storage block voltage threshold, cause the storage block to provide stored electrical energy to charge the target block to a second voltage.

25. A system comprising:
a processor;
an array of memory cells comprising a target block and a storage block;
a plurality of word lines coupled to the array of memory cells, and
a first memory controller; and
a second memory controller configured to perform a plurality of access operations comprising a first operation and a second operation, wherein the second memory controller is configured to:
during the first operation,
cause the target block to provide electrical energy to charge the storage block to a first voltage, and
discharge the word line coupled to the target block; and
during the second operation,
determine if the first voltage is greater than or equal to a storage block voltage threshold, and
in accordance with a determination that the first voltage is greater than or equal to the storage block voltage threshold, cause the storage block to provide stored electrical energy to charge the target block to a second voltage.
